(19) United States
(12) Patent Application Publication
(10) Pub. No.: US 2017/0241721 A1
(43) Pub. Date: Aug. 24, 2017

(54) HEAT SINK WITH DESIGNED THERMAL CONUDCTOR ARRANGEMENT

(71) Applicant: ENZOTECHNOLOGY CORP., CHINO, CA (US)

(72) Inventor: Kuo-An Liang, Taoyuan City (TW)

(21) Appl. No.: 15/212,822

(22) Filed: Jul. 18, 2016

(30) Foreign Application Priority Data
Feb. 19, 2016 (TW) 105202434

(51) Int. Cl. F28F 13/08; F28F 3/02; H05K 7/20; F28D 21/00

(52) U.S. Cl. CPC F28F 13/08; F28D 21/00; F28F 3/02; H05K 7/2039; F28D 2021/0029; F28F 2215/04

(57) ABSTRACT

A heat sink includes a base and plural thermal conductors. The base includes plural installation areas. The plural installation areas are in parallel with a first direction and separated from each other along a second direction. Each installation area includes a first lateral region, a second lateral region and a middle region. The plural thermal conductors are disposed on the corresponding installation areas. The thermal conductors on each installation area are classified into a first group and a second group. The thermal conductors of the first group are disposed on the first lateral region and in parallel with each other. The thermal conductors of the second group are disposed on the second lateral region and in parallel with each other. The thermal conductors of the first group are not in parallel with the thermal conductors of the second group.

### FIELD OF THE INVENTION

The present invention relates to a heat sink, and more particularly to a heat sink having designed thermal conductor arrangement for adjusting the distribution of airflow passing therethrough.

### BACKGROUND OF THE INVENTION

With development of science and technology, the performance of an electronic device is gradually increased. During operation of the electronic device, the electronic components of the electronic device generate heat. Consequently, the operating temperature is increased. The increased temperature may adversely affect the operation of the electronic device. Consequently, it is important to effectively dissipate away the heat and decrease the temperature of the electronic device.

Conventionally, a heat sink with high thermal conductivity is attached on the heat generation component of the electronic device in order to remove the heat. Since the heat sink is in close contact with the heat generation component, a heat transfer path with low thermal resistance is formed. Moreover, since the heat sink has plural fins, the contact area between the airflow and the heat sink is largely increased. Consequently, the use of the heat sink can increase the heat dissipating efficiency. For increasing heat dissipating efficiency, an active heat dissipation device (e.g., a fan) is used for driving airflow and guiding the airflow to the heat sink. Consequently, the heat can be transferred to the surroundings more efficiently. Moreover, according to finite element analysis, the middle regions of some kinds of heat generation components accumulate more heat. Since the fins of the conventional heat sink are in parallel with each other and uniformly distributed, the airflow passing through the fins is uniformly distributed. In other words, the conventional heat sink is not specially designed to remove the heat from the middle region of the heat sink, and thus the temperature at the middle region of the heat generation component is still high. For increasing the heat dissipating efficiency, it is necessary to increase the rotating speed of the fan. Under this circumstance, the power consumption and the generated noise are increased.

Therefore, there is a need of providing an improved heat sink in order to overcome the above drawbacks.

### SUMMARY OF THE INVENTION

An object of the present invention provides a heat sink. According to the airflow direction and the heat dissipating demand, the heat sink is specially designed to have a suitable thermal conductor arrangement. That is, the angles of the thermal conductors and the distribution density of the thermal conductors are adjusted according to the practical requirements. Moreover, since the wind resistance is reduced, the rotating speed of the fan can be decreased. Consequently, the noise generated by the fan is decreased, and the heat dissipating efficiency of the heat is enhanced.

Another object of the present invention provides a heat sink. The locations and angles of the thermal conductors of the heat sink are specially designed. Consequently, the driven airflow can be guided to specified regions (e.g., the middle regions) of the heat sink to remove more heat from the specified regions. Under this circumstance, the overall heat dissipating efficiency is enhanced.

In accordance with an aspect of the present invention, there is provided a heat sink. The heat sink includes a base and plural thermal conductors. The base includes plural installation areas. The plural installation areas are in parallel with a first direction, and the plural installation areas are separated from each other along a second direction. Each installation area includes a first lateral region, a second lateral region and a middle region between the first lateral region and the second lateral region. The plural thermal conductors are disposed on the corresponding installation areas. The thermal conductors on each installation area are classified into a first group and a second group. The thermal conductors of the first group are disposed on the first lateral region. The thermal conductors of the second group are disposed on the second lateral region. The thermal conductors of the first group are in parallel with each other. The thermal conductors of the second group are in parallel with each other. The thermal conductors of the first group are not in parallel with the thermal conductors of the second group.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a heat sink according to a first embodiment of the present invention;

FIG. 2 is a schematic top view illustrating the heat sink according to the first embodiment of the present invention;

FIG. 3 is a schematic top view illustrating a heat sink according to a second embodiment of the present invention; and

FIG. 4 is a schematic top view illustrating a heat sink according to a third embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. In the following embodiments and drawings, the elements irrelevant to the concepts of the present invention are omitted and not shown. For well understanding the present invention, the elements shown in the drawings are not in scale with the elements of the practical product.

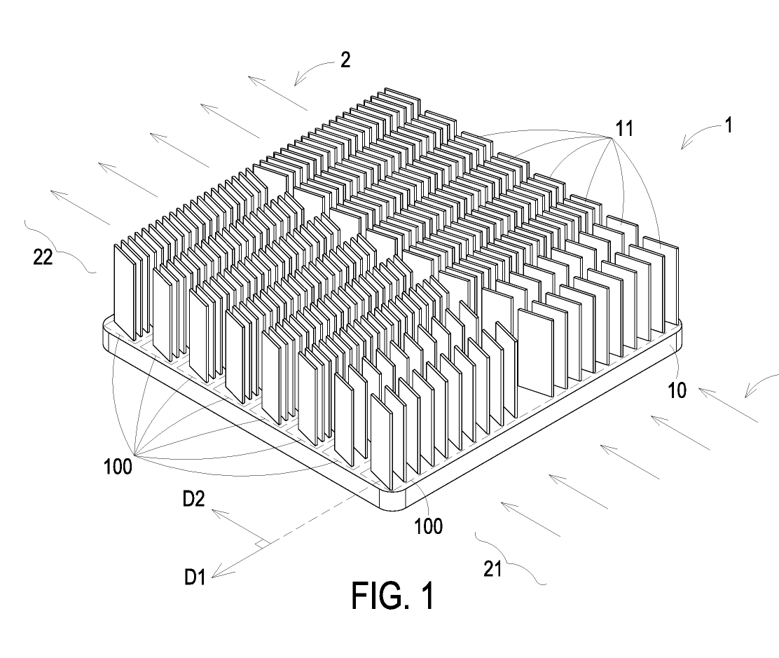

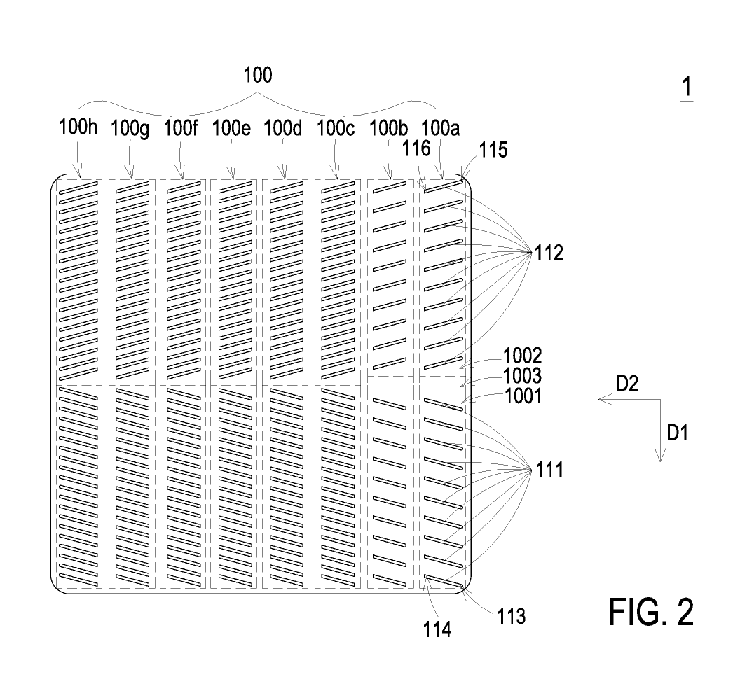

FIG. 1 is a schematic perspective view illustrating a heat sink according to a first embodiment of the present invention. FIG. 2 is a schematic top view illustrating the heat sink according to the first embodiment of the present invention. The heat sink is applicable to an active heat dissipation system 2 including for example but not limited to a fan or a blower. An airflow driven by the active heat dissipation system is introduced into the heat sink 1 from an upstream side 21 and exited to a downstream side 22. Consequently, the heat is transferred from the heat sink 1 to the surroundings. In this embodiment, the heat sink 1 comprises a base 10 and plural thermal conductors 11. The base 10 comprises plural installation areas 100. The plural installation areas 100 are in parallel with a first direction D1. Moreover, the plural installation areas 100 are separated from each other along a second direction D2. Preferably, the first direction D1 and the second direction D2 are perpendicular to each other. In this embodiment, the plural installation areas 100 comprise eight installation areas, including a first installation area 100a, a second installation area 100b, a third installation area 100c, a fourth installation area 100d, a fifth installation area 100e, a sixth installation area 100f, a seventh installation area 100g and an eighth installation area 100h. These eight installation areas 100 are all in parallel with the first direction D1 and separated from each other along the second direction D2. It is noted that the number of the installation areas 100 is not restricted. In particular, the number of the installation areas 100 is determined according to the size of the base 10 of the heat sink 1 and can be altered according to the practical requirements.

Please refer to FIGS. 1 and 2 again. Each installation area 100 comprises a first lateral region 1001, a second lateral region 1002 and a middle region 1003. The middle region 1003 is arranged between the first lateral region 1001 and the second lateral region 1002. The plural thermal conductors 11 are disposed on corresponding installation areas 100. As shown in FIG. 2, a specified number of separate thermal conductors 11 are disposed on each installation area 100. The shapes of the thermal conductors 11 are not restricted. For example, the shapes of the thermal conductors 11 include but not limited to sheets, cylinders, elliptical cylinders or arc cylinders. Moreover, the plural thermal conductors 11 on each installation area 100 are classified into two groups including for example but not limited to a first group 111 and a second group 112. The thermal conductors of the first group 111 are disposed on the first lateral region 1001 of the installation area 100. The thermal conductors of the second group 112 are disposed on the second lateral region 1002 of the installation area 100. The thermal conductors of the first group 111 are in parallel with each other. The thermal conductors of the second group 112 are in parallel with each other. The thermal conductors of the first group 111 are not in parallel with the thermal conductors of the second group 112. That is, the thermal conductors on the first lateral region 1001 and the thermal conductors on the second lateral region 1002 are not in parallel with the second direction D2, and the thermal conductors on the first lateral region 1001 are not in parallel with the thermal conductors on the second lateral region 1002. Since the thermal conductors on the first lateral region 1001 and the thermal conductors on the second lateral region 1002 are not in parallel with the second direction D2, the driven airflow is centralized to the middle region 1003 of the installation area 100. In comparison with the conventional heat sink, the heat dissipation efficiency in the middle region of the present heat sink is enhanced. Consequently, the overall heat dissipation efficiency of the heat sink of the present invention is enhanced.

In every two adjacent installation areas 100 of the heat sink 1, a first number of thermal conductors 11 are disposed on the installation area 100 closer to the upstream side 21, and a second number of thermal conductors 11 are disposed on the installation area 100 closer to the downstream side 22. The first number is not larger than the second number. Preferably but not exclusively, the thermal conductors of the first group 111 on the first lateral region 1001 are in parallel with each other and discretely arranged at regular intervals, and the thermal conductors of the second group 112 on the second lateral region 1002 are in parallel with each other and discretely arranged at regular intervals.

Please refer to FIG. 2 again. In this embodiment, the first installation area 100a, the second installation area 100b, the third installation area 100c, the fourth installation area 100d, the fifth installation area 100e, the sixth installation area 100f, the seventh installation area 100g and the eighth installation area 100h are sequentially distributed on the base 10 along the second direction D2. The eighth installation area 100h is the closest to the downstream side 22. The first installation area 100a is the closest to the upstream side 21. For example, the numbers of thermal conductors 11 disposed on the eight installation areas 100a, 100b, 100c, 100d, 100e, 100f, 100g and 100h are 40, 40, 40, 40, 40, 40, 20 and 20, respectively. In other words, the distribution density of the thermal conductors from the upstream side 21 to the downstream side 22 is gradually increased. It is noted that the numbers of thermal conductors on these installation areas are not restricted. That is, the numbers of thermal conductors on these installation areas are determined according to the size of the base 10 of the heat sink 1 and can be altered according to the practical requirements.

In the embodiment of FIG. 2, the plural thermal conductors 11 are sheet-like fins. Each thermal conductor 11 of the first group 111 has a first upstream end 113 and a first downstream end 114. Each thermal conductor 11 of the second group 112 has a second upstream end 115 and a second downstream end 116. The first upstream end 113 is closer to the upstream side 21 than the first downstream end 114. The second upstream end 115 is closer to the upstream side 21 than the second downstream end 116. Moreover, the distance between the first upstream end 113 of any thermal conductor 11 and the second upstream end 115 of any thermal conductor 11 is larger than the distance between the first downstream end 114 of the corresponding thermal conductor 11 and the second downstream end 116 of the corresponding thermal conductor 11. That is, the distances between any thermal conductor 11 of the first group 111 and any thermal conductor 11 of the second group 112 along the second direction D2 are gradually decreased. Consequently, the plural thermal conductors 11 from the upstream side 21 to the downstream side 22 are gradually converged to the middle regions 1003 of the installation areas 100.

Please refer to FIGS. 1 and 2 again. When the airflow is driven by the fan of the active heat dissipation system 2, the airflow is introduced into the heat sink 1 from the upstream side 21 and exited to the downstream side 22 along the second direction D2. As mentioned above, the plural thermal conductors 11 from the upstream side 21 to the downstream side 22 are gradually converged to the middle regions 1003 of the installation areas 100 and form flowing paths, the distribution density of the thermal conductors from the upstream side 21 to the downstream side 22 is gradually increased, and the driven airflow is centralized to the middle regions 1003 of the installation areas 100. Consequently, the flowrate of the airflow in the middle regions 1003 is higher than the flowrate of the airflow in first lateral region 1001 and the flowrate of the airflow in the second lateral region 1002. In comparison with the conventional heat sink, the heat dissipation efficiency in the middle regions of the present heat sink is enhanced. Consequently, the overall heat dissipation efficiency of the heat sink of the present invention is enhanced. Moreover, according to the airflow direction and the heat dissipating demand, the heat sink can be specially designed to have a suitable thermal conductor arrangement. That is, the angles of the thermal conductors and the distribution density of the thermal conductors can be adjusted according to the practical requirements. Moreover, since the wind resistance is reduced, the rotating speed of the fan can be decreased. Consequently, the noise generated by the fan is decreased, and the heat dissipating efficiency of the heat is still satisfied.

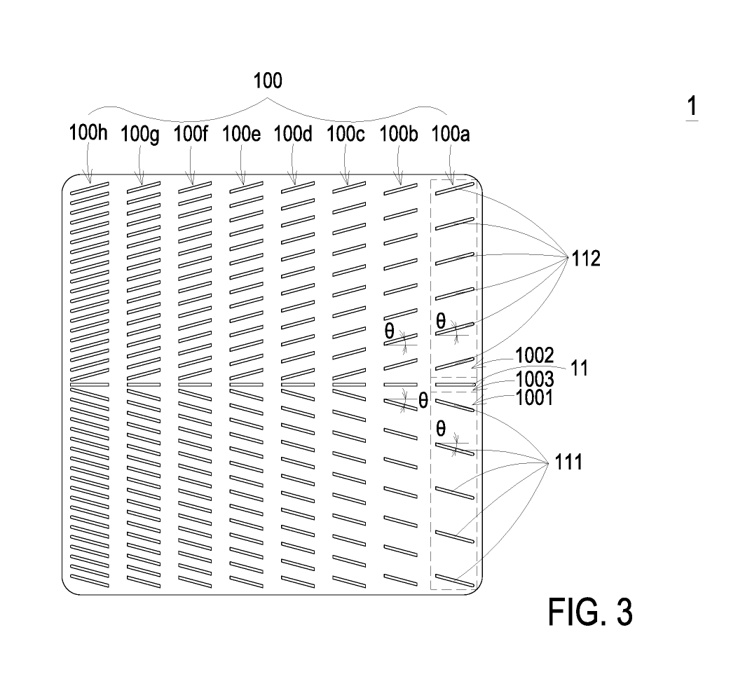

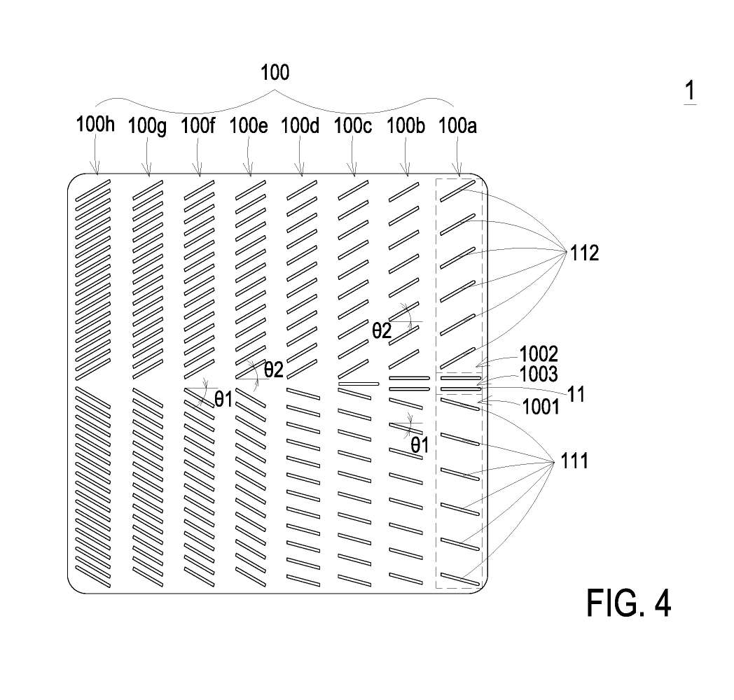

FIG. 3 is a schematic top view illustrating a heat sink according to a second embodiment of the present invention. FIG. 4 is a schematic top view illustrating a heat sink according to a third embodiment of the present invention. In the second embodiment and the third embodiment, the plural thermal conductors 11 are also sheet-like fins. Component parts and elements corresponding to those of the first embodiment are designated by identical numeral references, and detailed descriptions thereof are omitted.

As mentioned in the first embodiment of FIG. 2, the middle regions 1003 of all installation areas 100 are dummy areas without thermal conductors. The numbers of thermal conductors 11 disposed on the eight installation areas 100a, 100b, 100c, 100d, 100e, 100f, 100g and 100h are 40, 40, 40, 40, 40, 40, 20 and 20, respectively. That is, the numbers of thermal conductor on the two installation areas that are closer to the upstream side 21 are 20, and the numbers of thermal conductor on the six installation areas that are closer to the downstream side 22 are 40.

In the second embodiment of FIG. 3, the numbers of thermal conductors 11 disposed on the eight installation areas 100a, 100b, 100c, 100d, 100e, 100f, 100g and 100h are 12, 16, 21, 25, 29, 33, 37 and 41, respectively. That is, the numbers of thermal conductors 11 on the installation areas 100 of the heat sink 1 are gradually increased along the second direction D2. Moreover, in this embodiment, the middle region 1003 of each installation area 100 comprises at least one thermal conductor 11, which is in parallel with the second direction D2.

In the third embodiment of FIG. 4, only the middle regions 1003 of the installation areas 100a, 100b and 100c comprise thermal conductors 11, which are in parallel with the second direction D2. Moreover, the other installation areas 100d, 100e, 100f, 100g and 100h do not comprise thermal conductors. In other words, the middle regions of some installation areas are dummy areas without thermal conductors, and the middle regions of the other installation areas comprise thermal conductors 11, which are in parallel with the second direction D2.

Please refer to the first embodiment of FIG. 2 again. In each installation area, the numbers of the thermal conductor 11 of the first group 111 is equal to the numbers of the thermal conductor 11 of the second group 112. In addition, the thermal conductor 11 of the first group 111 and the thermal conductor 11 of the second group 112 are symmetrical to each other with respect to the middle region 1003.

Please refer to the second embodiment of FIG. 3 again. In the first installation area 100a and the second installation area 100b, the numbers of the thermal conductor 11 of the first group 111 is different from the numbers of the thermal conductor 11 of the second group 112. It is noted that the numbers of the thermal conductor 11 of the first group 111 and the numbers of the thermal conductor 11 of the second group 112 may be altered according to the practical requirements.

In the first embodiment and the second embodiment, the angle θ between each thermal conductor 111 of the first group 111 and the second direction D2 is equal to the angle θ between each thermal conductor 111 of the second group 112 and the second direction D2. In the third embodiment, a first angle θ1 between each thermal conductor 111 of the first group 111 and the second direction D2 is different from a second angle θ2 between each thermal conductor 111 of the second group 112 and the second direction D2. Since the tilt angles of the thermal conductors and the density distribution of the thermal conductors are specially designed, the airflow driven by the fan can be centralized to pass through a specified area of the heat sink 1. Consequently, the efficiency of removing the heat from the specified area is enhanced.

It is noted that numerous modifications and alterations may be made while retaining the teachings of the invention. For example, the angle θ between each thermal conductor 111 of the first group 111 and the second direction D2 is equal to the angle θ between each thermal conductor 111 of the second group 112 and the second direction D2 in the same installation area; but the angles θ in different installation areas are not always identical. For example, the angle θ is gradually decreased from the upstream side 21 to the downstream side 22 along the second direction D2. In another embodiment, the distribution density of the thermal conductors 11 of the first group 111 is gradually decreased from a first lateral side of the base 10 to the middle region 1003, and the distribution density of the thermal conductors 11 of the second group 112 is gradually decreased from a second lateral side of the base 10 to the middle region 1003.

In the above embodiments, the locations and angles of the thermal conductors of the heat sink are specially designed. Consequently, the driven airflow can be guided to specified regions of the heat sink to remove more heat from the specified regions. Under this circumstance, the overall heat dissipating efficiency is enhanced, the rotating speed of the fan is decreased, and the generated noise is reduced.

From the above descriptions, the present invention provides a heat sink. According to the airflow direction and the heat dissipating demand, the heat sink is specially designed to have a suitable thermal conductor arrangement. That is, the angles of the thermal conductors and the distribution density of the thermal conductors are adjusted according to the practical requirements. Moreover, since the wind resistance is reduced, the rotating speed of the fan can be decreased. Consequently, the noise generated by the fan is decreased, and the heat dissipating efficiency of the heat sink is enhanced. Moreover, the locations and angles of the thermal conductors of the heat sink are specially designed. Consequently, the driven airflow can be guided to specified regions (e.g. the middle regions) of the heat sink to remove more heat from the specified regions. Under this circumstance, the overall heat dissipating efficiency is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat sink, comprising:
a base comprising plural installation areas, wherein the plural installation areas are in parallel with a first direction, and the plural installation areas are separated from each other along a second direction, wherein each installation area comprises a first lateral region, a second lateral region and a middle region between the first lateral region and the second lateral region; and
plural thermal conductors disposed on the corresponding installation areas, wherein the thermal conductors on each installation area are classified into a first group and a second group, the thermal conductors of the first group are disposed on the first lateral region, and the thermal conductors of the second group are disposed on the second lateral region, wherein the thermal conductors of the first group are in parallel with each other, the thermal conductors of the second group are in parallel with each other, and the thermal conductors of the first group are not in parallel with the thermal conductors of the second group.

2. The heat sink according to claim 1, wherein the heat sink is applicable to an active heat dissipation system, and an airflow driven by the active heat dissipation system is introduced into the heat sink from an upstream side and exited to a downstream side, wherein in every two adjacent installation areas of the heat sink, a first number of thermal conductors are disposed on the installation area closer to the upstream side, and a second number of thermal conductors are disposed on the installation area closer to the downstream side, wherein the first number is not larger than the second number.

3. The heat sink according to claim 2, wherein a distribution density of the thermal conductors is gradually increased along the second direction.

4. The heat sink according to claim 2, wherein the first direction and the second direction are perpendicular to each other, and the thermal conductors are fins, wherein each thermal conductor of the first group has a first upstream end closer to the upstream side and a first downstream end closer to the downstream side, and each thermal conductor of the second group has a second upstream end closer to the upstream side and a second downstream end closer to the downstream side, wherein a distance between the first upstream end and the second upstream end is larger than the distance between the first downstream end and the second downstream end.

5. The heat sink according to claim 1, wherein the middle region of each installation area is a dummy area.

6. The heat sink according to claim 1, wherein the middle region of each installation area contains at least one thermal conductor, which is in parallel with the second direction.

7. The heat sink according to claim 1, wherein the middle region of at least one installation area is a dummy area, wherein the middle region of each of the other installation areas contains at least one thermal conductor, which is in parallel with the second direction.

8. The heat sink according to claim 1, wherein for each installation area, the thermal conductor of the first group and the thermal conductor of the second group are symmetrical to each other with respect to the middle region.

9. The heat sink according to claim 1, wherein the thermal conductors are fins, wherein a first angle between each thermal conductor of the first group and the second direction is different from a second angle between each thermal conductor of the second group and the second direction.

10. The heat sink according to claim 1, wherein the thermal conductors are fins, wherein an angle between each thermal conductor of the first group and the second direction is equal to an angle between each thermal conductor of the second group and the second direction.

11. The heat sink according to claim 1, wherein the thermal conductors are fins, wherein for the same installation area, an angle between each thermal conductor of the first group and the second direction is equal to an angle between each thermal conductor of the second group and the second direction, wherein for different installation areas, the angle between each thermal conductor of the first group and the second direction is different from the angle between each thermal conductor of the second group and the second direction.

12. The heat sink according to claim 1, wherein the thermal conductors are fins, the thermal conductors of the first group on the first lateral region are in parallel with each other and discretely arranged at regular intervals, and the thermal conductors of the second group on the second lateral region are in parallel with each other and discretely arranged at regular intervals.

13. The heat sink according to claim 1, wherein a distribution density of the thermal conductors of the first group on the first lateral region is gradually decreased from a first lateral side of the base to the middle region, and a distribution density of the thermal conductors of the second group on the second lateral region is gradually decreased from a second lateral side of the base to the middle region.
